(19) United States
(12) Patent Application Publication
(10) Pub. No.: US 2007/0300118 A1
(43) Pub. Date: Dec. 27, 2007

(54) Method and system for controlling multiple physical pin electronics channels in a semiconductor test head

(76) Inventor: Brad Reak, Ft. Collins, CO (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/448,385

(22) Filed: Jun. 6, 2006

(51) Int. Cl. G01R 31/28; G06F 11/00

(52) U.S. Cl. 714/742

(57) ABSTRACT

Methods and apparatuses for processing test execution instructions on a plurality of devices under test (DUTs) simultaneously include functionality for receiving a test instruction, extracting a specified DUT channel identifier from the test instruction, extracting an instruction from the test instruction, determining whether the instruction requires application of a stimulus signal or receipt of a response signal, obtaining the stimulus signal and simultaneously applying the stimulus signal to each PE channel that is mapped to the specified DUT channel identifier if the instruction requires application of the stimulus signal, and simultaneously receiving the response signal from each PE channel that is mapped to the specified DUT channel identifier if the instruction requires receipt of the response signal.

### BACKGROUND OF THE INVENTION

Semiconductor testers utilize complex hardware to test semiconductor devices such as integrated circuits. To test semiconductor devices, the tester applies test stimuli to, and receives test responses from, test points on the device. The semiconductor device test points are commonly called device under test (DUT) channels. Signals applied to the DUT channels require specific signal levels and timing generated by tester resources. The hardware connecting tester resources to physical pins of the tester that connect to the DUT channels are often called the pin electronics (PE) channels.

In conventional testers, each test instruction must specify the source of the signal data for each DUT channel of each DUT being tested. Semiconductor testers are becoming more sophisticated as semiconductor devices are simultaneously becoming more complicated. The end result is a higher DUT count capability per tester, and more DUT channels per DUT. This leads to more DUT channels that must be specified for every test instruction.

Often, a tester will test multiple identical DUTs for a given test run. However, because conventional tester hardware and software provides no support for simultaneously configuring and testing multiple identical DUTs, testing of the DUTs still requires specification for every DUT channel of every DUT, resulting in high testing overhead both in terms of test time and in test development time.

A need therefore exists for hardware and software support for simultaneously testing multiple identical DUTs, including simultaneous application of test stimuli to all corresponding respective input DUT channels of all identical DUTs, and simultaneous receiving of test responses from all corresponding respective DUT output channels of all identical DUTs.

### SUMMARY OF THE INVENTION

Embodiments of the invention include a method for processing test execution instructions on a plurality DUTs simultaneously, comprising receiving a test instruction; extracting a specified DUT channel identifier from the test instruction; extracting an instruction from the test instruction; determining whether the instruction requires application of a stimulus signal or receipt of a response signal; if the instruction requires application of a stimulus signal, obtaining the stimulus signal and simultaneously applying the stimulus signal to each pin electronics (PE) channel that is mapped to the specified DUT channel identifier; and if the instruction requires receipt of a response signal, simultaneously receiving the response signal from each PE channel that is mapped to the specified DUT channel identifier.

Embodiments of the invention include A semiconductor device tester which tests a plurality DUTs comprising channel mapping circuitry which maps DUT channels to pin electronics (PE) channels, the DUT channels comprising signal input and/or output channels of the DUT and the PE channels comprising signal input and/or output channels of the tester; and a processor which receives a test instruction, extracts at least one specified DUT channel identifier from the test instruction, and executes the test instruction simultaneously on each DUT, wherein the extracted DUT channel identifier designates a corresponding DUT channel on each of the plurality of DUTs, each of the corresponding DUT channels connected to a different PE channel of the tester to which the test instruction applies.

Embodiments of the invention include an apparatus which maps DUT channels to pin electronics (PE) channels, the DUT channels comprising signal input and/or output channels of the DUT and the PE channels comprising signal input and/or output channels of the tester, the apparatus comprising a channel mapping mechanism which stores associations of DUT channels to pin electronics (PE) channels, each association indicating a connection between a DUT channel of a DUT and a PE channel, wherein corresponding DUT channels on each of the DUTs have identical DUT channel identifiers but connect to different respective PE channels.

### BRIEF DESCRIPTION OF THE DRAWINGS

A more complete appreciation of this invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a block diagram of a semiconductor test system;

FIG. 2 is a pinout diagram of a memory chip that may embody each of the DUTs to be tested in the semiconductor test system of FIG. 1;

FIG. 3 is a schematic block diagram of an embodiment of a semiconductor device tester which tests a plurality of DUTs;

FIG. 4 shows an embodiment of a DUT-Channel-to-PE-Channel mapping circuit; and

FIG. 5 is a flowchart of an embodiment of a method for processing test execution instructions on a plurality DUTs simultaneously.

### DETAILED DESCRIPTION

For simplicity and illustrative purposes, the principles of the embodiments are described. Moreover, in the following detailed description, references are made to the accompanying figures, which illustrate specific embodiments. Electrical, mechanical, logical and structural changes may be made to the embodiments without departing from the spirit and scope of the embodiments.

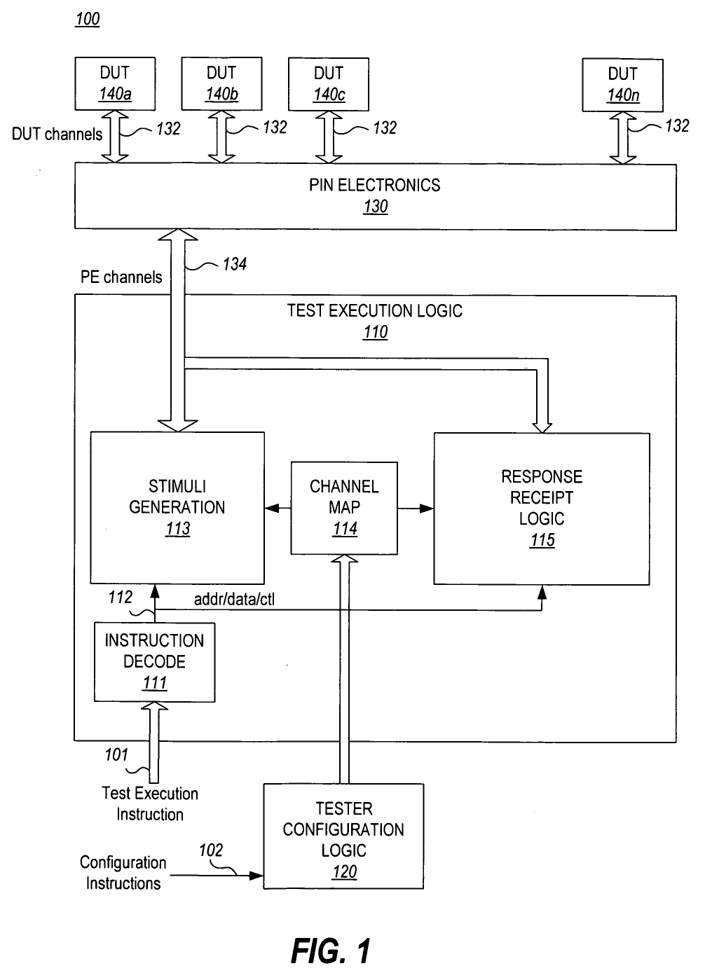

FIG. 1 shows a test environment for simultaneously testing a plurality of identical DUTs (140a through 140n). Stimulus signals may be applied to, and response signals may be received from, various DUT channels 132 by the DUTs 140a through 140n. Because the DUTs 140a through 140n are identical, the DUT channels 132 of each DUT correspond to identical corresponding DUT channels of every other identical DUT. However, each of the DUT channels 132 is connected to a different unique PE channel 134 in the tester.

As used herein, the term “DUT channel” may include a pin, a pad, a solder bump, a PCB test point, a trace, or any other conductive component on which electrical signal data is applied to or output from a DUT. The connection of DUT channels 132 to PE channels 134 is performed in the pin electronics circuitry 130, under control by test execution logic 110, typically using a set of programmable relays that are configured prior to execution of a test. The pin electronics 130 also includes circuitry necessary for generating signal level and timing and for converting signals received from DUT channels 132 into digital format.

The tester 100 includes test execution logic 110 which generates test stimuli to apply to the DUTs (140a through 140n) and which receives test response signals from the DUTs (140a through 140n). The values and timing of the stimuli to be applied to the DUTs is determined by test execution instructions 101.

The tester 100 may include test instruction decode circuitry 111 which receives and decodes test execution instructions 101 from an instruction bus and generates program address/data/control signals 112. Stimuli generation circuitry 113 is responsive to the program address/data/control signals 112 to generate stimuli on PE channels 134 as specified by the test execution instruction 101. In particular, the test execution instruction 101 may specify one or more respective DUT channels 132. For each specified DUT channel in the instruction, the stimuli generation circuitry 113 generates a stimulus signal on each of a plurality of PE channels connected to corresponding respective DUT channels associated with the specified DUT channel from the test instruction on each of the DUTs. A DUT-to-PE-Channel map 114 stores associations of DUT channels to PE channels, as described in more detail hereinafter. The map 114 is used by the stimuli generation circuitry 113 to route the stimulus signals to the PE channels that are connected to DUT channels as specified in the test execution instruction 101.

Test response receiving circuitry 115 is responsive to the program address/data/control signals 112 to capture signals from PE channels 134 as specified by a test execution instruction 101. In particular, the test execution instruction 101 may specify one or more respective DUT channels. For each specified DUT channel in the instruction 101, the response receiving circuitry 115 captures a response signal on each of a plurality of PE channels connected to corresponding respective DUT channels associated with the specified DUT channel from the test instruction on each of the DUTs. Which PE channels are connected to which DUT channels is stored in the DUT-to-PE-Channel Map 114. The map 114 is used by the response receiving circuitry 115 to route the response signals from the PE channels that are connected to DUT channels as specified in the test execution instruction 101.

The DUT-to-PE-Channel Map 114 is configurable to allow testing of DUTs implemented based on different DUT designs. The configuration of the DUT-to-PE-Channel Map 114 is performed prior to execution of a test. The configuration of the DUT-to-PE-Channel Map 114 is facilitated by test configuration logic 120, which is responsive to configuration instructions 122 to configure the DUT-to-PE-Channel Map 114 specific to the particular DUT design of the DUTs to be tested. The test configuration logic 120 is not active during actual execution of tests on the DUTs by the test execution logic 110.

Embodiments of the invention take advantage of the identicality of the DUTs 140a through 140n in simultaneously applying test stimuli to, and/or receiving test responses from, respective channels of identical DUTs.

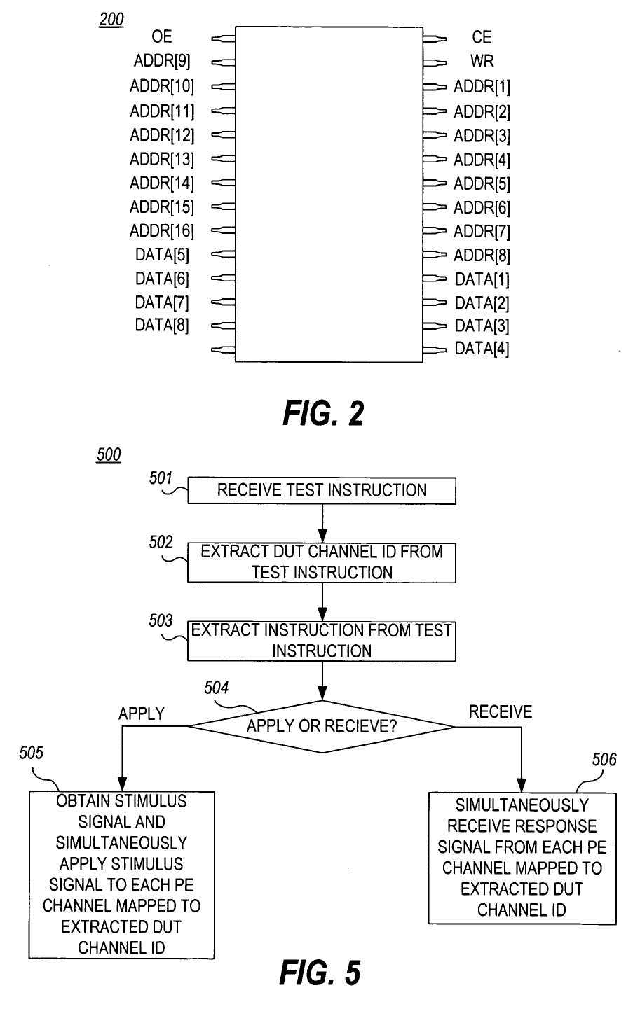

Physically, each pin (or other I/O terminal) of each DUT is mapped to a different PE channel. For example, suppose the tester 100 of FIG. 1 is configured to test thirty-six (n=36) memory chips that are identical by design, each having a 16-bit address bus (ADDR[1-16]), an 8-bit data bus (DATA[1 -8]), a chip enable pin (CE), an output enable (OE) pin, a write enable (WR) pin, and power and ground pins (not shown), as illustrated in FIG. 2, which shows a pinout diagram of a single DUT 200. TABLE 1 illustrates an example physical mapping between DUT channels and PE channels for a tester that tests 36 DUTs that embody the DUT 200 shown in FIG. 2.

TABLE 1

| PE Channel # | DUT # | Pin # | Signal Name |
|---|---|---|---|
| PE1 | 1 | 1 | ADDRESS[1] |
| PE2 | 1 | 2 | ADDRESS[2] |
| | . | | |
| | . | | |
| | . | | |
| PE16 | 1 | 16 | ADDRESS[16] |
| PE17 | 1 | 17 | DATA[1] |
| PE18 | 1 | 18 | DATA[2] |
| | . | | |
| | . | | |
| | . | | |
| PE24 | 1 | 24 | DATA[8] |
| PE25 | 1 | 25 | CE |
| PE26 | 1 | 26 | OE |
| PE27 | 1 | 27 | WR |
| PE28 | 2 | 1 | ADDRESS[1] |
| PE29 | 2 | 2 | ADDRESS[2] |
| | . | | |
| | . | | |
| | . | | |
| PE43 | 2 | 16 | ADDRESS[16] |
| PE44 | 2 | 17 | DATA[1] |
| PE45 | 2 | 18 | DATA[2] |
| | . | | |
| | . | | |
| | . | | |
| PE51 | 2 | 24 | DATA[8] |
| PE52 | 2 | 25 | CE |
| PE53 | 2 | 26 | OE |
| PE54 | 2 | 27 | WR |
| | . | | |
| | . | | |
| | . | | |
| PE946 | 36 | 1 | ADDRESS[1] |
| PE947 | 36 | 2 | ADDRESS[2] |
| | . | | |
| | . | | |
| | . | | |
| PE961 | 36 | 16 | ADDRESS[16] |
| PE962 | 36 | 17 | DATA[1] |
| PE963 | 36 | 18 | DATA[2] |
| | . | | |
| | . | | |
| | . | | |
| PE969 | 36 | 24 | DATA[8] |
| PE970 | 36 | 25 | CE |
| PE971 | 36 | 26 | OE |
| PE972 | 36 | 27 | WR |

While the actual number and mapping of PE channels to DUT channels will vary from DUT design to DUT design, what remains consistent is that in the execution of a given test stimulus/response, there exists a one-to-one mapping between physical PE channels and physical DUT channels. Said another way, every pin of every DUT to which a test stimulus is applied or from which a test response is received maps to a different PE channel in the tester.

Embodiments of the invention recognize that if more than one identical DUT is tested simultaneously, it is advantageous to be able to model all DUTs as identical collections of pins and to control all identical DUTs as if the tester were controlling only one such DUT. Rather than individually specifying for every test instruction the configuration of every DUT channel of every DUT, embodiments of the invention assigns, for every corresponding DUT channel on every DUT, a corresponding reference DUT channel. DUT-to-PE-Channel translation circuitry or software translates specified DUT channels contained in test execution instructions into all the PE channels corresponding to the reference DUT channel associated with the specified DUT channel from the instruction. Thus, a single instruction is applied to all DUTs simultaneously.

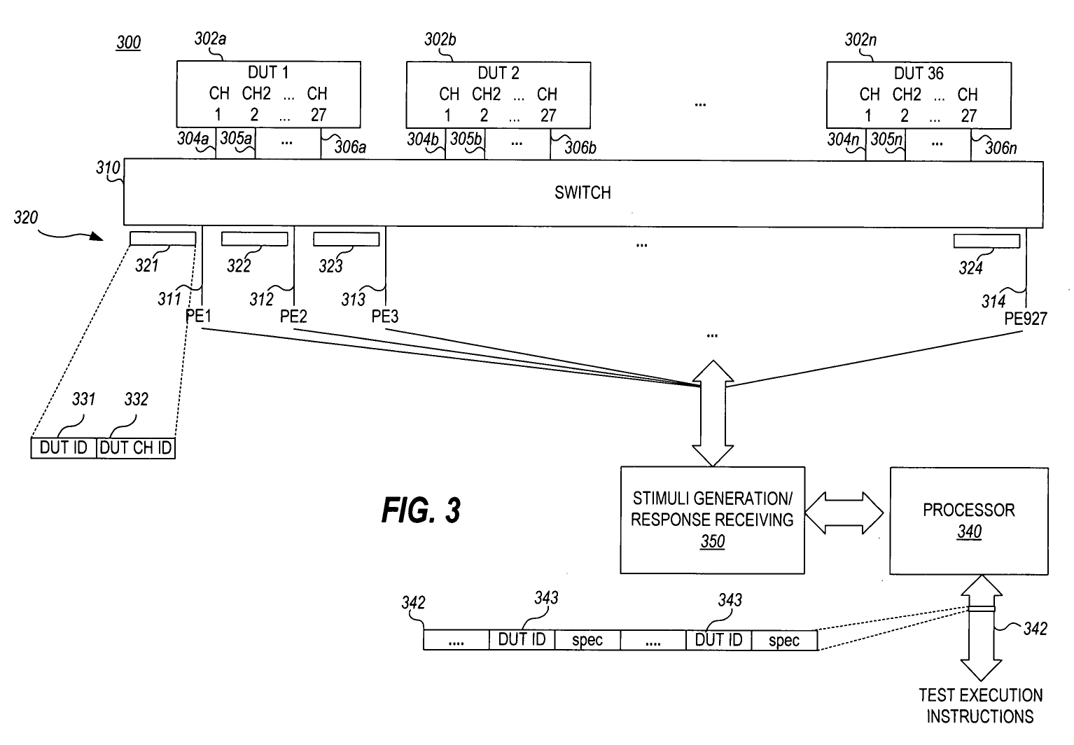

FIG. 3 is a schematic block diagram of an embodiment of a semiconductor device tester 300 which tests a plurality of devices under test (DUTs) 302a, 302b, 302n. In one embodiment, the plurality of DUTs 302a, 302b, 302n are identical. The tester 300 includes DUT-Channel-to-PE-Channel mapping circuitry 320, which maps DUT channels 304a, 305a, 306a, 304b, 305b, 306b, 304n, 305n, 306n to pin electronics (PE) channels 311, 312, 313, 314. The DUT channels 304a, 305a, 306a, 304b, 305b, 306b, 304n, 305n, 306n are signal input and/or output channels of the DUTs 302a, 302b, 302n. The PE channels 311, 312, 313, 314 are signal input and/or output channels of the tester 300.

The tester 300 also includes a processor 340 which receives test execution instructions 342. The processor 340 extracts at least one specified DUT channel identifier (ID) 343 from a test execution instruction 342. A given test execution instruction 342 will typically include a number of DUT channel IDs equal to the number of DUT channels for one DUT, where each DUT channel ID corresponds to each corresponding DUT channel of each DUT. Each extracted DUT channel ID 343 designates a corresponding DUT channel (304a through 304n, or 305a through 305n, or 306a through 306n) on each of the plurality of DUTs (302a through 302n). Each of the corresponding DUT channels are connected to a different PE channel (311 through 314) of the tester to which the test execution instruction 342 applies. The processor 340, through control of stimuli generation/response receiving circuitry 350, executes the test instruction simultaneously on each DUT 302a, 302b, 302n.

In one embodiment, the DUT-Channel-to-PE-Channel mapping circuitry 320 comprises a lookup table (e.g., TABLE 2 below) comprising an entry for each DUT channel, each entry comprising one or more PE channels associated with the DUT channel corresponding to the entry. The lookup table may be stored in computer memory. The processor 340 may access the lookup table to determine which PE channels are associated with a specified DUT channel, for example as extracted (343) from a test execution instruction (342).

For example, in the example above in which n (where n=36) identical memory chips are simultaneously tested, each corresponding pin of each DUT may be associated with a single DUT channel identifier. Thus, pin 1 of DUT 1 may be associated with DUT channel 1, and corresponding pin 1 of DUTs 2 through 36 may also be associated with DUT channel 1. Associated with DUT channel 1, then, are each of the corresponding PE channel connected to pin 1 of each of the DUTs. Similarly, pin 2 of DUT 1 may be associated with DUT channel 2, and corresponding pin 2 of DUTs 2 through 36 may also be associated with DUT channel 2. Associated with DUT channel 2, then, are each of the corresponding PE channels connected to pin 2 of each of the DUTs. TABLE 2 illustrates an example DUT-Channel-to-Pin-Electronics-Channel map in the form of a lookup table that may be used during testing of these n identical memory chips.

TABLE 2

| Signal Name | DUT Channel # | PE Channel # |
|---|---|---|
| ADDRESS[1] | 1 | PE1, PE28, . . . , |
| | | PE946 |
| ADDRESS[2] | 2 | PE 2, PE29, . . . , |
| | | PE947 |
| . | . | . |
| . | . | . |
| . | . | . |
| ADDRESS[16] | 16 | PE16, PE43, . . . , |
| | | PE961 |
| DATA[1] | 17 | PE17, PE44, . . . , |
| | | PE962 |
| DATA[2] | 18 | PE18, PE45, . . . , |
| | | PE963 |
| . | . | . |
| . | . | . |
| . | . | . |
| DATA[8] | 24 | PE24, PE51, . . . , |
| | | PE969 |
| CE | 25 | PE25, PE52, . . . , |
| | | PE970 |
| OE | 26 | PE26, PE53, . . . , |
| | | PE971 |
| WR | 27 | PE27, PE54, . . . , |
| | | PE972 |

As shown, each DUT channel (associated with a respective DUT channel number) is mapped to the corresponding PE channels connected to the corresponding respective DUT channel of each of the plurality of DUTs. Thus, a single tester instruction 342 may specify an instruction (e.g., application of a stimulus signal or receipt of a response signal) associated with a specified DUT channel, and the instruction will be carried on the specified DUT channel of all DUTs simultaneously.

In one embodiment, the DUT-Channel-to-PE-Channel mapping circuitry 320 comprises a DUT channel mapping register 321, 322, 323, 324 associated with each PE channel 311, 312, 313, 314 in the tester 300. During test setup, each DUT channel mapping register 321, 322, 323, 324 is loaded with a DUT ID 331 and a DUT channel ID 332 corresponding to the respective DUT and DUT channel to which the associated PE channel is connected to prior to testing the DUTs. Corresponding DUT channels on each of the DUTs (302a through 302n) have identical DUT channel IDs.

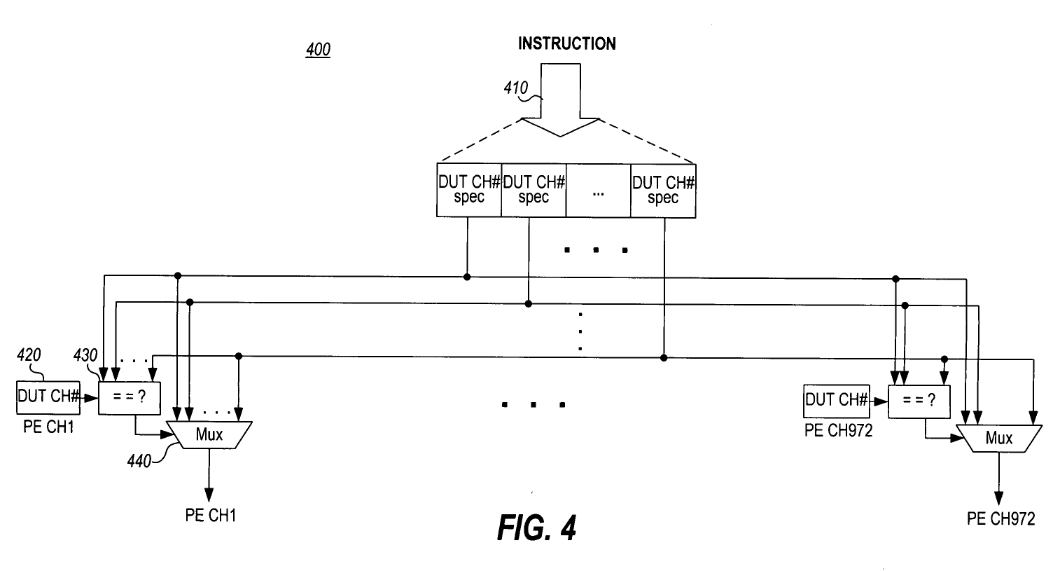

FIG. 4 shows an embodiment 400 of the DUT-Channel-to-PE-Channel mapping circuitry 320 of FIG. 3, for the example of 36 DUTs of FIG. 2 (and as also shown in the mapping of TABLE 2). As illustrated, each PE channel has associated with it a Channel Map register 420, a comparator 430, and a multiplexer 440. The Channel Map register 420 of each PE channel is loaded with the DUT identifier 422 and channel identifier 424 of the DUT. The channel identifier 424 is identical for each corresponding pin of each DUT, while the DUT identifier is different for each DUT.

Each comparator 430 receives at least the specified channel IDs extracted from the tester execution instruction 410. The comparator 430 compares the extracted specified channel IDs to the DUT channel ID stored in the associated Channel Map register 420, and outputs a select signal that indicates only one of the extracted specified channel IDs.

Meanwhile, at least the instruction portion (which may include control data or stimulus data) associated with each of the extracted specified channel IDs from the tester execution instruction is input to the data inputs of each of the multiplexers 440. The respective select signal for each respective multiplexer is the respective output of the respective comparator associated with the respective PE channel. The select signal selects only one of the instruction portion associated with each of the extracted specified channel IDs from the tester execution instruction 410. Thus, each PE channel associated with a given DUT channel ID simultaneously receives the same instruction as specified in the instruction portion of the corresponding extracted specified DUT channel ID of the test execution instruction 410.

FIG. 5 is a flowchart illustrating an embodiment of a method 500 for processing test execution instructions on a plurality DUTs simultaneously. The method includes the steps of receiving a test execution instruction (step 501); extracting a specified DUT channel ID from the test execution instruction (step 502); extracting an instruction from the test execution instruction (step 503); determining whether the instruction requires application of a stimulus signal or receipt of a response signal (step 504); if the instruction requires application of a stimulus signal, obtaining the stimulus signal and simultaneously applying the stimulus signal to each PE channel that is mapped to the specified DUT channel ID (step 505); and if the instruction requires receipt of a response signal, simultaneously receiving the response signal from each PE channel that is mapped to the specified DUT channel ID (step 506). In one embodiment, the plurality of DUTs are identical.

However the DUT-Channel-to-Pin-Electronics-Channel mapping function is implemented, it operates to allow a single test instruction having an instruction for one DUT to be applied to all identical DUTs simultaneously. Thus, rather than requiring a separate specification in the tester instruction for each pin electronics channel associated with a given DUT channel, a single tester instruction with a single specification for each DUT channel of a given DUT may be executed on all DUTs simultaneously.

Those of skill in the art will appreciate that the invented method and apparatus described and illustrated herein may be implemented in software, firmware or hardware, or any suitable combination thereof. Preferably, the method and apparatus are implemented in software, for purposes of low cost and flexibility. Thus, those of skill in the art will appreciate that the method and apparatus of the invention may be implemented by a computer or microprocessor process in which instructions are executed, the instructions being stored for execution on a computer-readable medium and being executed by any suitable instruction processor. Alternative embodiments are contemplated, however, and are within the spirit and scope of the invention.

Although this preferred embodiment of the present invention has been disclosed for illustrative purposes, those skilled in the art will appreciate that various modifications, additions and substitutions are possible, without departing from the scope and spirit of the invention as disclosed in the accompanying claims.

What is claimed is:

1. A method for processing test execution instructions on a plurality devices under test (DUTs) simultaneously, comprising:
receiving a test instruction;
extracting a specified DUT channel identifier from the test instruction;
extracting an instruction from the test instruction;
determining whether the instruction requires application of a stimulus signal or receipt of a response signal;
if the instruction requires application of a stimulus signal, obtaining the stimulus signal and simultaneously applying the stimulus signal to each pin electronics (PE) channel that is mapped to the specified DUT channel identifier; and
if the instruction requires receipt of a response signal, simultaneously receiving the response signal from each PE channel that is mapped to the specified DUT channel identifier.

2. The method of claim 1, wherein the plurality of DUTs are identical.

3. A semiconductor device tester which tests a plurality of devices under test (DUTs), comprising:
channel mapping circuitry which maps DUT channels to pin electronics (PE) channels, the DUT channels comprising signal input and/or output channels of the DUT and the PE channels comprising signal input and/or output channels of the tester; and
a processor which receives a test instruction, extracts at least one specified DUT channel identifier from the test instruction, and executes the test instruction simultaneously on each DUT, wherein the extracted DUT channel identifier designates a corresponding DUT channel on each of the plurality of DUTs, each of the corresponding DUT channels connected to a different PE channel of the tester to which the test instruction applies.

4. The semiconductor device tester of claim 3, wherein the plurality of DUTs are identical.

5. The semiconductor device tester of claim 3, wherein the channel mapping circuitry comprises a DUT channel mapping register associated with each PE channel in the tester which is loaded with a DUT channel identifier corresponding to a DUT channel to which the associated PE channel is connected prior to testing the DUTs, wherein corresponding DUT channels on each of the DUTs have identical DUT channel identifiers.

6. An apparatus which maps device under test (DUT) channels to pin electronics (PE) channels, the DUT channels comprising signal input and/or output channels of the DUT and the PE channels comprising signal input and/or output channels of the tester, the apparatus comprising:
a channel mapping mechanism which stores associations of DUT channels to pin electronics (PE) channels, each association indicating a connection between a DUT channel of a DUT and a PE channel, wherein corresponding DUT channels on each of the DUTs have identical DUT channel identifiers but connect to different respective PE channels.

7. The apparatus of claim 6, wherein the channel mapping mechanism comprises a DUT channel mapping register associated with each PE channel in the tester which is loaded with a DUT channel identifier corresponding to a DUT channel to which the associated PE channel is connected prior to testing the DUTs.

8. The apparatus of claim 6, wherein the channel mapping mechanism comprises a lookup table comprising an entry for each DUT channel, each entry comprising one or more PE channels associated with the DUT channel corresponding to the entry.
